(19) United States
(12) Patent Application Publication
(10) Pub. No.: US 2022/0374688 A1
(43) Pub. Date: Nov. 24, 2022

(54) TRAINING METHOD OF NEURAL NETWORK BASED ON MEMRISTOR AND TRAINING DEVICE THEREOF

(71) Applicant: TSINGHUA UNIVERSITY, Beijing (CN)

(72) Inventors: Huaqiang WU, Beijing (CN); Peng YAO, Beijing (CN); Bin GAO, Beijing (CN); Qingtian ZHANG, Beijing (CN); He QIAN, Beijing (CN)

(73) Assignee: TSINGHUA UNIVERSITY, Beijing (CN)

(21) Appl. No.: 17/049,349

(22) PCT Filed: Mar. 6, 2020
(86) PCT No.: PCT/CN2020/078203

§ 371 Date: Oct. 21, 2020

(30) Foreign Application Priority Data
Nov. 1, 2019 (CN) 201911059194.1

(51) Int. Cl. G06N 3/063; G06N 3/04; G06N 3/08

(52) U.S. Cl. CPC G06N 3/063; G06N 3/049; G06N 3/08

(57) ABSTRACT

A training method and a training device for a neural network based on memristors are provided. The neural network includes a plurality of neuron layers connected one by one and weight parameters between the plurality of neuron layers, and the training method includes: training the weight parameters of the neural network, and programming a memristor array based on the weight parameters after being trained to write the weight parameters after being trained into the memristor array; and updating a critical layer or several critical layers of the weight parameters of the neural network by adjusting conductance values of at least part of memristors of the memristor array.

### CROSS-REFERENCE TO RELATED APPLICATION

The present application claims priority of Chinese Patent Application No. 201911059194.1, filed on Nov. 1, 2019, and the entire content disclosed by the Chinese patent application is incorporated herein by reference as part of the present application.

### TECHNICAL FIELD

The embodiments of the present disclosure relate to a training method and a training device for a neural network based on memristors.

### BACKGROUND

The rise of deep neural network algorithms has brought about a revolution in intelligent information technology. Based on various deep neural network algorithms, image recognition and segmentation, object detection, and translation and generation of speech and text can be achieved. Using deep neural network algorithms to process different workloads is a type of data-centric computing. The hardware platform for implementing the deep neural network algorithm needs to have high-performance and low-power processing capabilities. However, the traditional hardware platform for implementing the deep neural network algorithm is based on the von Neumann architecture where storage and computing are separated. This architecture requires data to be moved back and forth between a storage device and a computing device during calculation, and therefore, in the calculation process of the deep neural network containing a large amount of parameters, the energy efficiency of the architecture is low. To this end, developing a new type of computing hardware to run deep neural network algorithms has become an urgent problem to be solved.

### SUMMARY

At least one embodiment of the present disclosure provides a training method for a neural network based on memristors, the neural network comprises a plurality of neuron layers connected one by one and weight parameters between the plurality of neuron layers, and the training method comprises: training the weight parameters of the neural network, and programming a memristor array based on the weight parameters after being trained to write the weight parameters after being trained into the memristor array; and updating at least one layer of the weight parameters of the neural network by adjusting conductance values of at least part of memristors of the memristor array.

For example, in the training method provided by at least one embodiment of the present disclosure, training the weight parameters of the neural network, and programming the memristor array based on the weight parameters after being trained to write the weight parameters after being trained into the memristor array, comprises: in a process of training the weight parameters of the neural network, according to a constraint of a conductance state of the memristor array, directly obtaining quantized weight parameters of the neural network, and writing the quantized weight parameters into the memristor array.

For example, in the training method provided by at least one embodiment of the present disclosure, training the weight parameters of the neural network, and programming the memristor array based on the weight parameters after being trained to write the weight parameters after being trained into the memristor array, comprises: performing a quantization operation on the weight parameters after being trained based on a constraint of a conductance state of the memristor array to obtain quantized weight parameters; and writing the quantized weight parameters into the memristor array.

For example, in the training method provided by at least one embodiment of the present disclosure, the quantization operation comprises uniform quantization and non-uniform quantization.

For example, in the training method provided by at least one embodiment of the present disclosure, writing the quantized weight parameters into the memristor array comprises: acquiring a target interval of the conductance state of the memristor array based on the quantized weight parameters; judging whether conductance states of respective memristors of the memristor array are within the target interval or not; if not, judging whether the conductance states of the respective memristors of the memristor array exceeds the target interval, if yes, applying a reverse pulse, and if not, applying a forward pulse; and if yes, writing the quantized weight parameters into the memristor array.

For example, in the training method provided by at least one embodiment of the present disclosure, updating the at least one layer of the weight parameters of the neural network by adjusting the conductance values of the at least part of memristors of the memristor array comprises: training the memristor array through a forward calculation operation and a reverse calculation operation; and applying a forward voltage or a reverse voltage to the at least part of memristors of the memristor array based on a result of the forward calculation operation and a result of the reverse calculation operation to update the conductance values of the at least part of memristors of the memristor array.

For example, in the training method provided by at least one embodiment of the present disclosure, the reverse calculation operation is performed only on the at least part of memristors of the memristor array.

For example, in the training method provided by at least one embodiment of the present disclosure, the memristor array comprises memristors arranged in an array with a plurality of rows and a plurality of columns, and training the memristor array through the forward calculation operation and the reverse calculation operation comprises: performing the forward calculation operation and the reverse calculation operation on the memristors, which are arranged in the plurality of rows and the plurality of columns, of the memristor array row by row or column by column or in parallel as a whole.

For example, in the training method provided by at least one embodiment of the present disclosure, weight parameters corresponding to the at least part of memristors of the memristor array are updated row by row or column by column.

For example, in the training method provided by at least one embodiment of the present disclosure, the forward calculation operation and the reverse calculation operation use only part of training set data to train the memristor array.

For example, in the training method provided by at least one embodiment of the present disclosure, updating the at least one layer of the weight parameters of the neural network by adjusting the conductance values of the at least part of memristors of the memristor array comprises: updating a last layer or last several layers of weight parameters in the neural network.

For example, the training method provided by at least one embodiment of the present disclosure further comprises: the memristor array outputting an output result of the neural network based on the weight parameters that are updated.

At least one embodiment of the present disclosure also provides a training device for a neural network based on memristors, and the training device comprises: an off-chip training unit, configured to train weight parameters of the neural network, and program a memristor array based on the weight parameters after being trained to write the weight parameters after being trained into the memristor array; and an on-chip training unit, configured to update at least one layer of the weight parameters of the neural network by adjusting conductance values of at least part of memristors of the memristor array.

For example, in the training device provided by at least one embodiment of the present disclosure, the off-chip training unit comprises an input unit and a read-write unit, and the on-chip training unit comprises a calculation unit, an update unit, and an output unit; the input unit is configured to input the weight parameters after being trained; the read-write unit is configured to write the weight parameters after being trained into the memristor array; the calculation unit is configured to train the memristor array through a forward calculation operation and a reverse calculation operation; the update unit is configured to apply a forward voltage or a reverse voltage to the at least part of memristors of the memristor array based on a result of the forward calculation operation and a result of the reverse calculation operation to update weight parameters corresponding to the at least part of memristors of the memristor array; and the output unit is configured to calculate an output result of the neural network based on the weight parameters that are updated.

For example, in the training device provided by at least one embodiment of the present disclosure, the off-chip training unit further comprises a quantization unit, the quantization unit is configured to, in a process of training the weight parameters of the neural network, according to a constraint of a conductance state of the memristor array, directly obtain quantized weight parameters of the neural network, and write the quantized weight parameters into the memristor array; or configured to perform a quantization operation on the weight parameters after being trained based on the constraint of the conductance state of the memristor array to obtain the quantized weight parameters.

For example, in the training device provided by at least one embodiment of the present disclosure, the calculation unit is configured to perform the reverse calculation operation only on at least part of memristors of the memristor array.

For example, in the training device provided by at least one embodiment of the present disclosure, the memristor array comprises memristors arranged in an array with a plurality of rows and a plurality of columns, the calculation unit is configured to perform the forward calculation operation and the reverse calculation operation on the memristors, which are arranged in the plurality of rows and the plurality of columns, of the memristor array row by row or column by column or in parallel as a whole.

For example, in the training device provided by at least one embodiment of the present disclosure, the update unit is configured to update the weight parameters corresponding to the at least part of memristors of the memristor array row by row or column by column.

For example, in the training device provided by at least one embodiment of the present disclosure, the on-chip training unit is further configured to update a last layer or last several layers of weight parameters in the neural network.

### BRIEF DESCRIPTION OF THE DRAWINGS

In order to clearly illustrate the technical solutions of the embodiments of the disclosure, the drawings of the embodiments will be briefly described in the following; it is obvious that the described drawings are only related to some embodiments of the disclosure and thus are not limitative to the disclosure.

FIG. 1 is a structural schematic diagram of a neural network;

FIG. 2 is a structural schematic diagram of a memristor array;

FIG. 3 is a flowchart of a training method provided by at least one embodiment of the present disclosure;

FIG. 4 is a schematic diagram of the training method described in FIG. 3;

FIG. 5 is a flowchart of an example of a training method provided by at least one embodiment of the present disclosure;

FIG. 6 is a schematic diagram showing cumulative probabilities of a memristor under 32 conductance states provided by at least one embodiment of the present disclosure;

FIG. 7 is a flowchart of another example of a training method provided by at least one embodiment of the present disclosure;

FIG. 8 is a schematic diagram of a weight parameter distribution provided by at least one embodiment of the present disclosure;

FIG. 9 is a flowchart of writing weight parameters into a memristor array provided by at least one embodiment of the present disclosure;

FIG. 10 is a flowchart of still another example of a training method provided by at least one embodiment of the present disclosure;

FIG. 11A is a schematic diagram of a forward calculation operation provided by at least one embodiment of the present disclosure;

FIG. 11B is a schematic diagram of a reverse calculation operation provided by at least one embodiment of the present disclosure;

FIG. 11C is a schematic diagram of an update operation provided by at least one embodiment of the present disclosure;

FIGS. 12A-12D are schematic diagrams of example manners of a forward calculation operation provided by at least one embodiment of the present disclosure;

FIGS. 13A-13D are schematic diagrams of example manners of a reverse calculation operation provided by at least one embodiment of the present disclosure;

FIGS. 14A-14D are schematic diagrams of example manners of an update operation provided by at least one embodiment of the present disclosure;

FIG. 15 is a schematic block diagram of a training device for a neural network provided by at least one embodiment of the present disclosure;

FIG. 16 is a schematic block diagram of an example of a training device provided by at least one embodiment of the present disclosure; and

FIG. 17 is a schematic block diagram of another example of a training device provided by at least one embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms such as “a,” “an,” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

Memristor-type devices (resistive random access memory, phase change memory, conductive bridge memory, etc.) are non-volatile devices, conductance states of which can be adjusted by applying external excitation. According to Kirchhoff s current law and Ohm's law, an array including such devices can perform multiply-accumulate calculations in parallel, and storage and calculation occur in each device of the array. Based on this computing architecture, it is possible to implement the storage-calculation integrated calculation that does not require a large amount of data movement. At the same time, multiply-accumulate is the core computing task required to run a neural network. Therefore, using the conductance value of the memristor-type device in the array to represent the weight value, a highly energy-efficient neural network operation can be achieved based on the storage-calculation integrated calculation.

Currently, there are two main implementation methods for implementing deep neural network algorithms based on storage-calculation integrated calculation. One method is the on-chip training (in-situ training) method, that is, all the conductance weights of the neural network are obtained based on in-situ training. In this method, based on the actual conductance weights, the forward and reverse calculations of the algorithm are implemented, and the conductance values of the weights are adjusted, and the entire training process is iterated continuously until the algorithm converges. The other method is the off-chip training method, that is, the weight values of the network are trained to obtain on other hardware, and then the devices in the array are programmed to the conductance states corresponding to the corresponding weight values according to the weight targets.

Memristor-type devices have various non-ideal characteristics, such as inconsistency among the devices due to deviations of physical mechanisms and manufacturing processes of the memristor-type devices. At the same time, due to the huge weight scale of deep neural networks, a plurality of memristor arrays are required to implement to fully map the weight parameters of deep neural networks. In this way, there are random fluctuations between different arrays and different devices of the same array, and at the same time, there are problems, such as device failure and device conductance state drift caused by device yield. In the case where the deep neural network algorithm is implemented based on the storage-calculation integrated calculation, the non-ideal characteristics of these devices will cause the system function to degrade, for example, appearing the phenomenon that the accuracy rate of target recognition decreases.

For example, in the case of using the on-chip training method to obtain all the weight parameters, although the weight parameters can be adjusted by an adaptive algorithm, multiple end-to-end training iterations are required, and the process is complicated (for example, the process is achieved through the residual reverse transmission algorithm of the convolutional layer, etc.), the hardware cost required is huge; at the same time, due to the limitation of the non-linearity and asymmetry of the weight adjustment process of the memristor-type device, it is difficult to efficiently implement deep neural networks with high performance (such as high recognition rate) through on-chip training.

For example, after using the off-chip training method to train the weight parameters, the trained weight parameters are programmed into the memristor array, that is, the conductance values of the respective devices in the memristor array are used to represent the weight parameters of the neural network, so that the memristor array integrated with storage-calculation integrated calculation can be used to achieve the inference calculation function of the neural network. This method can use the existing computing platform to complete the training, but during the process of weight programming, due to the influence of non-ideal characteristics, such as device yield problems, inconsistency, conductance drift, and random fluctuations, errors are inevitably introduced in the process of writing the weight to the device conductance, thereby causing the performance of the neural network system to decrease.

At least one embodiment of the present disclosure provides a training method for a neural network based on memristors. The neural network includes a plurality of neuron layers connected one by one and weight parameters between the plurality of neuron layers. The training method comprises: training the weight parameters of the neural network, and programming a memristor array based on the weight parameters after being trained to write the weight parameters after being trained into the memristor array; and updating at least one layer of the weight parameters of the neural network by adjusting conductance values of at least part of memristors of the memristor array.

Embodiments of the present disclosure also provide a training device corresponding to the above training method.

The training method and the training device provided by the embodiments of the present disclosure make up for the shortcomings of the on-chip training method and the off-chip training method used in the case where the neural network system is deployed in the hardware system based on the memristor array, and from the perspective of the neural network system, the training method and the training device can solve the problem, such as the performance degradation of the neural network system caused by non-ideal characteristics such as device fluctuations, and efficiently and cost-effectively deploys various neural networks in the hardware system based on the memristor array.

The embodiments and examples of the present disclosure will be described in detail below with reference to the drawings.

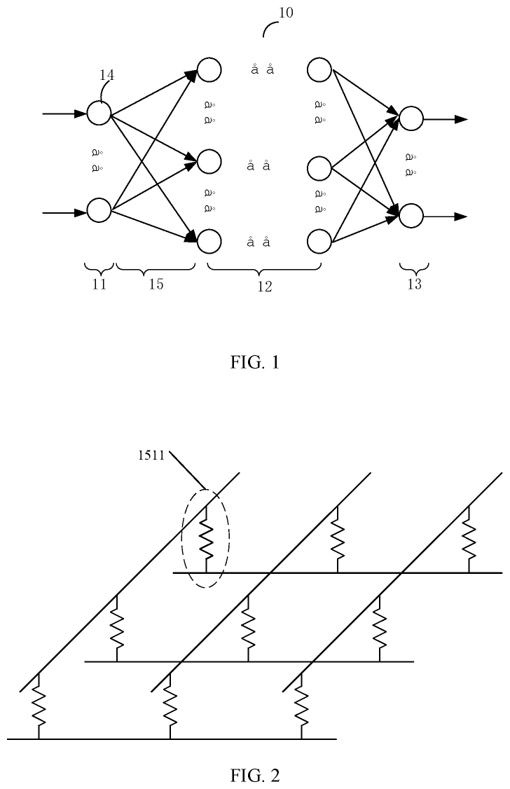

As shown in FIG. 1, the neural network 10 includes an input layer 11, at least one hidden layer 12, and an output layer 13. For example, the neural network 10 includes L (N is an integer greater than or equal to 3) neuron layers connected one by one. For example, the input layer 11 includes a first neuron layer, and at least one hidden layer 12 includes a second neuron layer to a (L−1)-th neuron layer, and the output layer 13 includes a L-th neuron layer. For example, the input layer 11 transmits the received input data to the at least one hidden layer 12, and the at least one hidden layer 12 performs layer-by-layer calculation conversion on the input data and sends the input data to the output layer 13, and the output layer 13 outputs the output result of the neural network 10. For example, as shown in FIG. 1, the layers of the neural network 10 are fully connected.

As shown in FIG. 1, each of the group consisting of the input layer 11, at least one hidden layer 12, and the output layer 13 includes a plurality of neuron nodes 14, and the amount of neuron nodes 14 in each layer may be set according to different application situations. For example, in the case where there are M (M is an integer greater than 1) input data, the input layer 11 has M neuron nodes 14.

As shown in FIG. 1, two adjacent neuron layers of the neural network 10 are connected by a weight parameter network 15. For example, the weight parameter network is implemented by a memristor array as shown in FIG. 2. For example, the weight parameter can be directly programmed as the conductance value of the memristor array. For example, the weight parameter may also be mapped to the conductance value of the memristor array according to a certain rule. For example, a difference between conductance values of two memristors can also be used to represent a weight parameter. Although the present disclosure describes the technical solution of the present disclosure by taking a case of directly programming the weight parameters as the conductance values of the memristor array or mapping the weight parameters to the conductance values of the memristor array according to a certain rule as an example, the case is only exemplary and is not a limitation on the present disclosure.

As shown in FIG. 2, the memristor array may include a plurality of memristors arranged in an array, such as a memristor 1511. For example, according to Kirchhoff s law, an output current of the memristor array can be obtained according to the following formula:

iⱼ=Σᵢ₌₁^{M}(vᵢg_{i,j}),

where i=1, . . . , M, j=1, . . . , n, n and M are all integers greater than 1.

In the above formula, vi represents a voltage excitation input by a neuron node i in the input layer, iⱼ represents the output current of a neuron node j in the next layer, and g_{i,j} represents the conductance matrix of the memristor array.

For example, the memristor array has a threshold voltage, and in the case where the amplitude of the input voltage is less than the threshold voltage of the memristor array, the conductance values of the memristor array are not changed. In this case, it can be calculated by inputting a voltage less than the threshold voltage and using the conductance value of the memristor; the conductance value of the memristor can be changed by inputting a voltage greater than the threshold voltage.

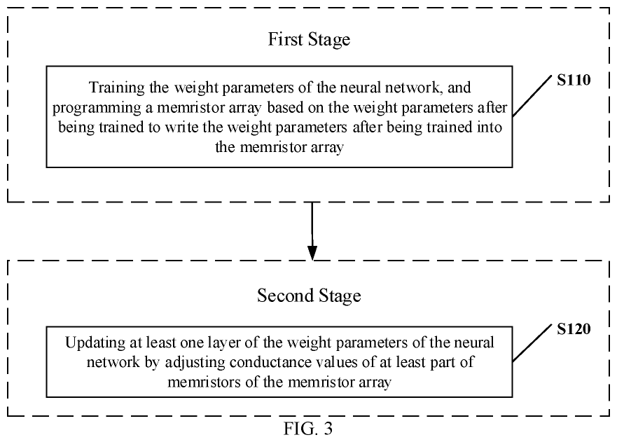

At least one embodiment of the present disclosure provides a training method for a neural network base on memristors. FIG. 3 is a flowchart of the training method, and FIG. 4 is a schematic diagram of the training method. The training method can be implemented in software, hardware, firmware, or any combination thereof. The training method for a neural network provided by the embodiments of the present disclosure will be described in detail below with reference to FIGS. 3 and 4. As shown in FIG. 3, the training method for the neural network includes step S110 and step S120.

Step S110: training the weight parameters of the neural network, and programming a memristor array based on the weight parameters after being trained to write the weight parameters after being trained into the memristor array.

Step S120: updating at least one layer of the weight parameters of the neural network by adjusting conductance values of at least part of memristors of the memristor array.

For example, in the embodiment of the present disclosure, the training method is a hybrid training method. For example, step S110 is an off-chip training process, that is, the training process before the weight parameters are written into the memristor array, and step S120 is an on-chip training process, that is, the training process after the weight parameters are written into the memristor array. In the traditional on-chip training process, the weight parameters of the entire neural network need to be updated, and in the hybrid training method provided by the embodiment of the present disclosure, for example, as shown in FIG. 4, after performing the off-chip training on the weight parameters of the neural network 10 in step S110, the trained weight parameters are written into the memristor array. In the on-chip training process described in step 5120, it is only necessary to update and adjust a critical layer or several critical layers of weight parameter in the neural network, that is, it is not necessary to update all the weight parameters represented by all the conductance values of the memristor array, which can greatly simplify the complexity of the memristor neural network system, reduce the cost of the neural network system, and reduce the implementation cost of the neural network system in the case where non-ideal characteristics, such as device yield problems, inconsistency, conductance drift, and random fluctuations, are compatible.

In addition, during the off-chip training process of the weight parameters of the neural network 10 provided in the embodiment of the present disclosure in step 5110, it may not need to consider the constraints when the weight parameters are written to the memristor array, that is, the non-ideal factors of the memristor device can not be considered in the off-chip training process, as long as the weights are obtained through the basic algorithm, which can simplify the off-chip training process of the neural network. Of course, the constraints when writing to the memristor array can also be considered, and the embodiments of the present disclosure are not limited thereto.

The hybrid training process of the neural network is described in detail below.

For step S110, performing off-chip training on the neural network to obtain the weight parameters of the neural network. For example, in this step, the step further includes quantizing the weight parameters according to the constraint of the conductance state of the memristor array used, to program quantized weight parameters into the memristor array. In the off-chip training process, if the performance constraint of the memristor has been taken into account, the quantized weight values that meets the characteristics of the memristor can be directly obtained. If the performance constraint of the memristor is not considered during training, the weight parameters after being trained need to be uniformly or non-uniformly quantized according to the conductance state of the memristor to obtain target weight parameters that can be used for programming.

For example, in some examples, the characteristics of the memristor device may be considered in the process of training the weight parameters of the neural network, for example, the constraint of the value range of the conductance value of each memristor in the memristor array (i.e., the constraint of the conductance state of the memristor array) is considered. That is, in the process of the off-chip training of the weight parameters of the neural network, the weight parameters are constrained according to the value ranges of the conductance values of respective memristors in the memristor array. In this case, the weight parameters after being trained can be directly written into the memristor array without scaling.

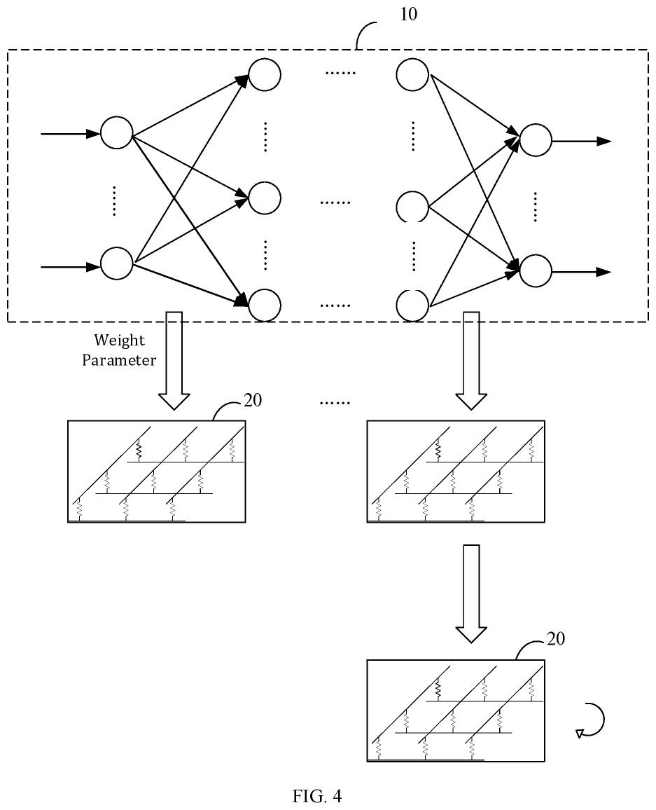

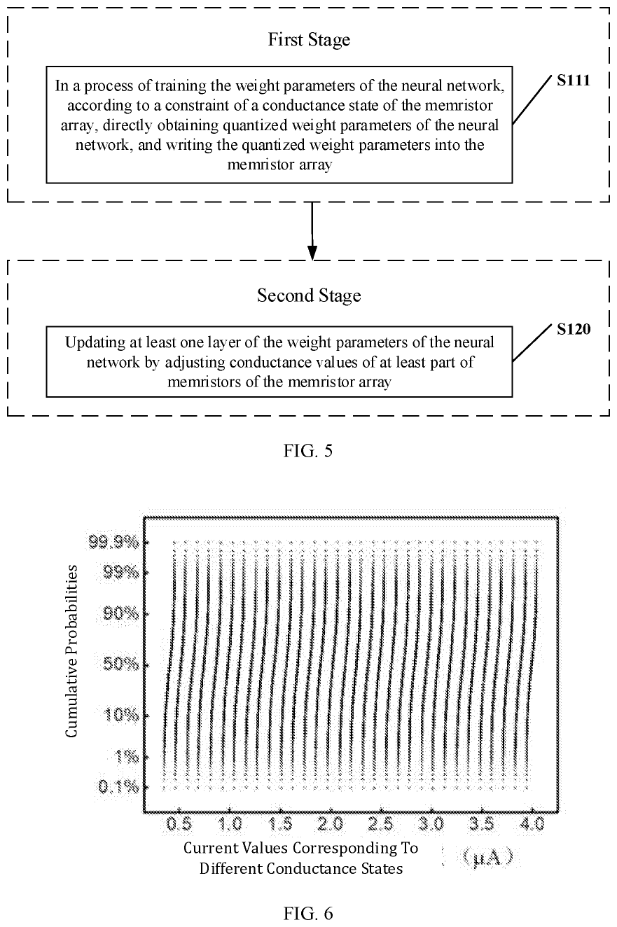

For example, FIG. 5 is a flowchart of at least one example of step S110 as shown in FIG. 3. In the example shown in FIG. 5, step S110 includes step S111.

Step S111: in a process of training the weight parameters of the neural network, according to a constraint of a conductance state of the memristor array, directly obtaining quantized weight parameters of the neural network, and writing the quantized weight parameters into the memristor array.

For example, the conductance state is usually represented by a corresponding read current at a fixed read voltage. The following embodiments are the same as those described herein and similar portions will not be repeated. For example, in some examples, it is assumed that the value range of the conductance values of the memristor array, into which the weight parameter of the neural network can be programmed, is (−3, −2, −1, 0, 1, 2, 3). Then, in the process of training the weight parameters of the neural network, according to the constraint of the conductance state of the memristor array, the quantized weight parameters in the range (−3, −2, −1, 0, 1, 2, 3) can be directly obtained, for example, and then the quantized weight parameter can be directly written into the memristor array without scaling.

It should be noted that the constraint of the conductance state of the memristor array and the values of the corresponding quantized weight parameters are determined according to the actual situations, and the embodiments of the present disclosure are not limited to this case. For example, FIG. 6 is a schematic diagram showing cumulative probabilities of a memristor under 32 conductance states provided by at least one embodiment of the present disclosure. As shown in FIG. 6, the cumulative probabilities of the memristor under 32 conductance states do not overlap each other, and the cumulative probability in each conductance state can reach more than 99.9%, indicating that the memristor array obtained according to the training method has good consistency under 32 conductance states.

For example, in other examples, the characteristics of the system and the device may not be considered during the off-chip training process of the weight parameters of the neural network, that is, the constraint characteristics of the value range of the conductance values of respective memristors in the memristor array may not be considered.

In this case, the scaling operation, such as a quantization operation, needs to be performed on the weight parameters after being trained according to the value range of the conductance values of the memristor array, that is, after scaling the weight parameters after being trained to the same range as the value range of the conductance values of the memristor array, the weight parameters after being trained are written into the memristor array.

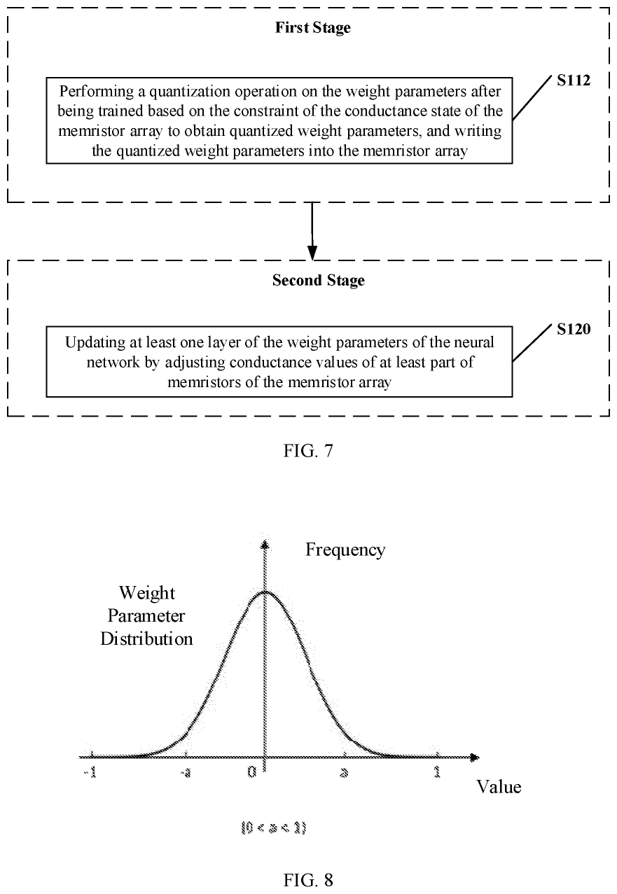

For example, FIG. 7 is a flowchart of at least another example of step S110 as shown in FIG. 3. In the example shown in FIG. 7, step S110 includes step S112.

Step S112: performing a quantization operation on the weight parameters after being trained based on the constraint of the conductance state of the memristor array to obtain quantized weight parameters, and writing the quantized weight parameters into the memristor array.

For example, the conductance state is usually represented by a corresponding read current at a fixed read voltage. For example, in this example, it is assumed that the value range (that is, the constraint of the conductance state) of the conductance values of the memristor array, into which the weight parameters of the neural network can be programmed, is (−3, −2, −1, 0, 1, 2, 3).

For example, without considering the characteristics of the memristor, the weight parameters after being trained are, for example, continuous values from −1 to 1 and expressed by floating point numbers. According to the constraint of the conductance state of the memristor array, the quantization operation quantizes the continuous weight parameters into, for example, the weight parameters in the range of (−3, −2, −1, 0, 1, 2, 3), and then writes the quantized weight parameters into the memristor array.

It should be noted that the constraint of the conductance state of the memristor array and the values of the corresponding quantized weight parameters are determined according to the actual situation, and the embodiments of the present disclosure are not limited to this case.

For example, the quantization operation includes uniform quantization and non-uniform quantization.

For example, FIG. 8 shows an example of a weight parameter distribution. In the example shown in FIG. 8, the weight parameters after being trained are continuous values from −1 to 1 and expressed by floating point numbers. For the uniform quantization, the whole interval from −1 to 1 is evenly divided into 7 intervals. For example, the quantized weight parameters are evenly divided into (−15, −10, −5, 0, 5, 10, 15), so that the quantized weight parameters correspond to the constraints (−3, −2, −1, 0, 1, 2, 3) of the conductance states, for example, each of the quantized weight parameters is an integer multiple, such as 5 times, of the constraint of the corresponding conductance state, which is not limited by the embodiments of the present disclosure. For the non-uniform quantization, the whole interval (−a, a) is evenly divided into 5 intervals, which correspond to the quantized weight parameters of (−2, −1, 0, 1, 2), a is greater than 0 and less than 1. For example, the interval (−1, −a) after being scaled corresponds to −3 in the constraints of the conductance states, and the interval (a, 1) corresponds to 3 in the constraints of the conductance states. The interval division in the quantization operation and the corresponding relationship between the interval and the weight parameter can be set according to specific circumstances, and the embodiments of the present disclosure are not limited thereto.

In order to more accurately write the quantized weight parameters (for example, the quantized weight parameters acquired in step S111 and step S112) into the memristor array, for example, bidirectional write verification may be adopted.

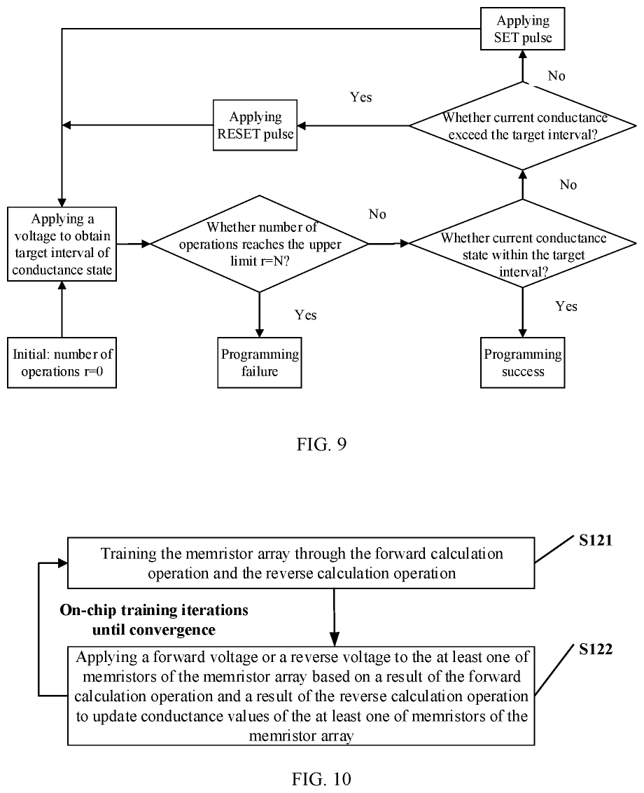

FIG. 9 is a flowchart of writing weight parameters into a memristor array according to at least one embodiment of the present disclosure. As shown in FIG. 9, the process of writing the weight parameters into the memristor array includes the following steps.

The target interval of the conductance state of each memristor device of the memristor array is obtained based on the quantized weight parameters. For example, the current, which corresponds to the conductance state of the memristor device, is usually obtained by applying a fixed voltage. The target interval of the conductance state can be expressed as (Iₜ−Δl, lₜ+Δl) , where Iₜ is the current value of the conductance state under the certain read voltage, and Δl is a current error tolerance corresponding to the conductance state.

The steps includes: judging whether the conductance states I of respective memristor devices in the memristor array is within the target interval or not, that is, judging whether Iₜ−Δl≤I≤Iₜ+ΔI is satisfied;

if yes, the quantized weight parameter is successfully written into the memristor array;

if not, judging whether the conductance state of each memristor device in the memristor array exceeds the target interval, that is, judging whether l>lₜ+Δl is satisfied:

if yes, applying a reverse pulse (RESET pulse);

if not, applying a forward pulse (SET pulse).

For example, in the bidirectional write verification process described in FIG. 9, the maximum number of operations N (N is an integer greater than 0) can also be set to limit the maximum number of operations. Hereinafter, the bidirectional write verification process is described systematically.

For example, first, an initial operation number r=0, the target interval of the conductance state is acquired, and the target interval of the conductance state can be expressed as (lₜ−Δl, lₜ+Δl) . Judging whether the number of operations reaches the maximum number of operations N, that is, judging whether r (r is greater than or equal to 0 and less than or equal to N) is equal to N, if yes, and the conductance state of the memristor is not within the target interval, it means that the programming is failed; if not, judging whether the current conductance state is within the target interval, if yes, it means that the programming is successful; if not, judging whether the conductance value of the current memristor exceeds the target interval, if yes, applying a reverse pulse (RESET pulse), if not, applying a forward pulse (SET pulse) to achieve to adjust the conductance value of the current memristor; and then, the above operations are repeated until the number of operations reaches the maximum number of operations N or the programming is successful. So far, the weight parameters after being trained can be written into the memristor array.

For example, an off-chip training unit can be provided, and the weight parameters of the neural network can be trained by the off-chip training unit; for example, the off-chip training unit can also be achieved by a central processing unit (CPU), a field programmable logic gate array (FPGA), or other forms of processing units with data processing capabilities and/or instruction execution capabilities, and corresponding computer instructions. For example, the processing unit may be a general-purpose processor or a dedicated processor, and may be a processor based on X86 or ARM architecture.

For step S120, for example, the storage-calculation integrate calculation is performed on the memristor array into which the weight parameters are written, and based on the result of the storage-calculation integrate calculation, the conductance values of at least part of the memristors in the memristor array are adjusted to update at least one layer of the weight parameters of the neural network.

For example, the storage-calculation integrated calculation may be a forward calculation operation and a reverse calculation operation, but the embodiments of the present disclosure are not limited thereto.

For example, the update operation may be implemented by applying a forward voltage or a reverse voltage to at least one layer of weight parameters, but the embodiments of the present disclosure are not limited thereto.

For example, FIG. 10 is a flowchart of at least one example of step S120 as shown in FIG. 3. In the example shown in FIG. 10, the training method includes step S121 and step 122.

Step S121: training the memristor array through the forward calculation operation and the reverse calculation operation.

Step S122: applying a forward voltage or a reverse voltage to the at least part of memristors of the memristor array based on a result of the forward calculation operation and a result of the reverse calculation operation to update conductance values the partial memristors of the memristor array.

For example, as shown in FIG. 10, the forward calculation operation and the reverse calculation operation are performed on the memristor array, into which the weight parameters after being trained are written, and the conductance values of at least part of the memristors are updated based on the result of the forward calculation operation and the result of the reverse calculation operation, to adjust the weight parameters corresponding to the at least part of the memristors, and finally, after a plurality of cycles of training iterations until convergence, non-ideal characteristics, such as device yield problems, inconsistencies, conductance drift, and random fluctuations, can be adaptively compatible, thereby restoring system performance, for example, improving recognition accuracy.

For example, a memristor has a threshold voltage, and in the case where the amplitude of the input voltage is less than the threshold voltage of the memristor, the conductance values of the memristor array are not changed. In this case, the forward calculation operation and the reverse calculation operation are achieved by inputting an input voltage less than the threshold voltage, and the update operation is achieved by inputting an input voltage greater than the threshold voltage. The processes of the forward calculation operation, the reverse calculation operation, and the update operation provided by at least one embodiment of the present disclosure will be described in detail below with reference to the drawings.

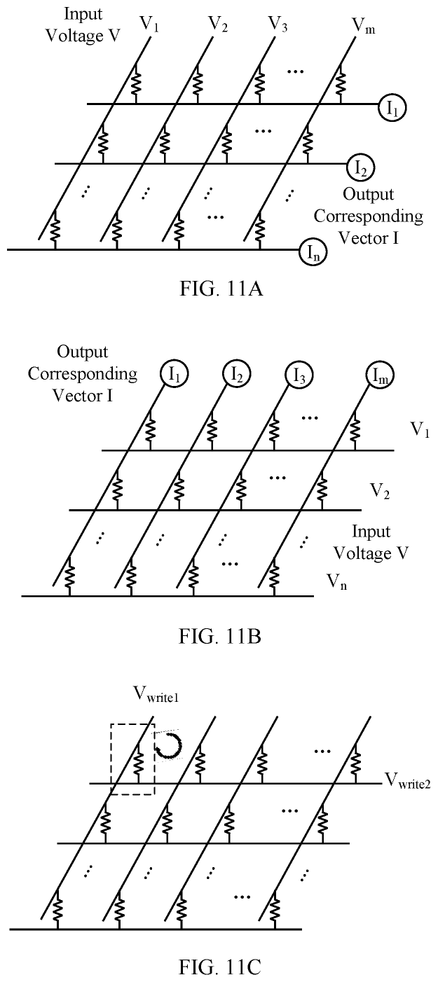

FIG. 11A is a schematic diagram of a forward calculation operation provided by at least one embodiment of the present disclosure. As shown in FIG. 11A, it is assumed that the equivalent conductance weight parameter matrix of the memristor array is [symbol] the input is a voltage V less than the threshold voltage of the memristor array, and the output is the corresponding current l , then the forward calculation operation of the corresponding neural network in this case can be expressed as: l= [symbol] .

FIG. 11B is a schematic diagram of a reverse calculation operation provided by at least one embodiment of the present disclosure. As shown in FIG. 11B, assuming that the equivalent conductance weight parameter matrix of the memristor array is [symbol] the input is a voltage V less than the threshold voltage of the memristor array, and the output is the corresponding current V , then the reverse calculation operation of the corresponding neural network can be expressed as: l= [symbol] .

FIG. 11C is a schematic diagram of an update operation provided by at least one embodiment of the present disclosure. As shown in FIG. 11C, assuming that the equivalent conductance weight parameter matrix of the memristor array is [symbol] , the input is a voltage Vwnte greater than the threshold voltage of the memristor array, then the update operation of the corresponding neural network can be expressed as: W=W_{new}. For example, if the update operation is to increase the conductance value of at least one memristor of the memristor array, a forward voltage is applied to an upper electrode and a lower electrode of the at least one memristor, such as the V_{write1} and V_{write2} shown in FIG. 11C; if the update operation is to reduce the conductance value of at least one memristor of the memristor array, a reverse voltage is applied to an upper electrode and a lower electrode of the at least one memristor, such as the V_{write1} and V_{write2} shown in FIG. 11C.

For example, in step S121, the forward calculation operation is performed on all memristor arrays of the neural network, and the reverse calculation operation is performed on at least part of the memristors in the memristor array of the neural network. Because for the hybrid training method, during the on-chip training process, only one critical layer or several critical layers of weight parameters in the neural network need to be adjusted, and therefore, the reverse calculation operation and the update operation only need to be performed on the critical layer or several critical layers in the neural network, thereby reducing system overhead and reducing system implementation costs.

For example, in the training method provided by at least one embodiment of the present disclosure, the forward calculation operation and the reverse calculation operation are performed on the memristor array row by row or column by column or in parallel as a whole.

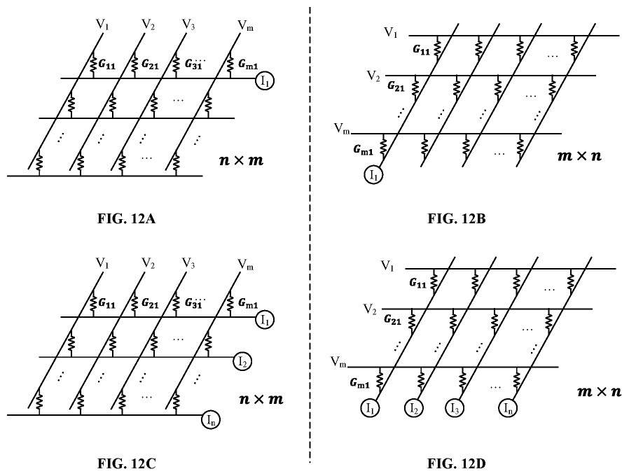

FIGS. 12A˜12D are schematic diagrams of example manners of a forward calculation operation provided by at least one embodiment of the present disclosure. FIG. 12A illustrates an example manner of performing a forward calculation operation row by row, in this example, assuming that the equivalent conductance weight parameter matrix of the memristor array is a n×m matrix, voltages V₁, V₂, V₃ . . . Vₘ less than the threshold voltage of the memristor array are input, and the corresponding currents l₁, I₂, l₃ . . . lₙ are output row by row. FIG. 12B illustrates an example manner of performing a forward calculation operation column by column, in this example, assuming that the equivalent conductance weight parameter matrix of the memristor array is a n×m matrix, voltages V₁, V₂, V₃ . . . Vₘ less than the threshold voltage of the memristor array are input, the corresponding currents l₁, l₂, l₃ . . . lₙ are output column by column. FIG. 12C illustrates an example manner of performing a forward calculation operation in parallel as a whole, in this example, assuming that the equivalent conductance weight parameter matrix of the memristor array is a n×m matrix, voltages V₁, V₂, V₃ . . . Vₘ less than the threshold voltage of the memristor array are input, the corresponding currents l₁, l₂, l₃ . . . lₙ of the respective rows are output in parallel as a whole. FIG. 12D illustrates an example manner of performing a forward calculation operation in parallel as a whole, in this example, assuming that the equivalent conductance weight parameter matrix of the memristor array is a n×m matrix, voltages V₁, V₂, V₃ . . . Vₘ less than the threshold voltage of the memristor array are input, the corresponding currents l₁, l₂, l₃ . . . lₙ of the respective columns are output in parallel as a whole.

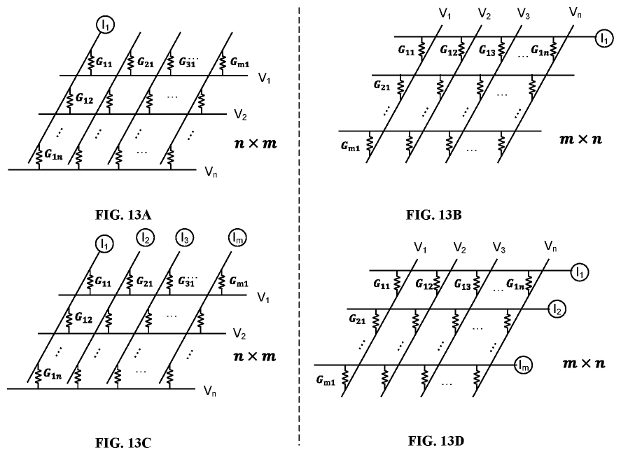

FIGS. 13A˜13D are schematic diagrams of example manners of a reverse calculation operation provided by at least one embodiment of the present disclosure. FIG. 13A illustrates an example manner of performing a reverse calculation operation column by column, in this example, assuming that the equivalent conductance weight parameter matrix of the memristor array is a n×m matrix, voltages V₁, V₂, V₃ . . . Vₙ smaller than the threshold voltage of the memristor array are input to the output terminal of the memristor array, and the corresponding currents l₁, l₂, l₃ . . . lₘ are output column by column. FIG. 13B illustrates an example manner of performing a reverse calculation operation row by row, in this example, assuming that the equivalent conductance weight parameter matrix of the memristor array is a n×m matrix, voltages V₁, V₂, V₃ . . . Vₙ smaller than the threshold voltage of the memristor array are input, and the corresponding currents l₁, l₂, l₃ . . . lₘ are output row by row. FIG. 13C illustrates an example manner of performing a reverse calculation operation in parallel as a whole, in this example, assuming that the equivalent conductance weight parameter matrix of the memristor array is a n×m matrix, voltages V₁, V₂, V₃ . . . Vₙ smaller than the threshold voltage of the memristor array are input, and the corresponding currents l₁, l₂, l₃ . . . lₘ of the respective columns are output in parallel as a whole. FIG. 13D illustrates an example manner of performing a reverse calculation operation in parallel as a whole, in this example, assuming that the equivalent conductance weight parameter matrix of the memristor array is a n×m matrix, voltages V₁, V₂, V₃ . . . Vₙ smaller than the threshold voltage of the memristor array are input, and the corresponding currents l₁, l₂, l₃ . . . lₘ of the respective rows are output in parallel as a whole.

For example, in the training method provided by at least one embodiment of the present disclosure, the weight parameters corresponding to at least part of the memristors of the memristor array are updated row by row or column by column.

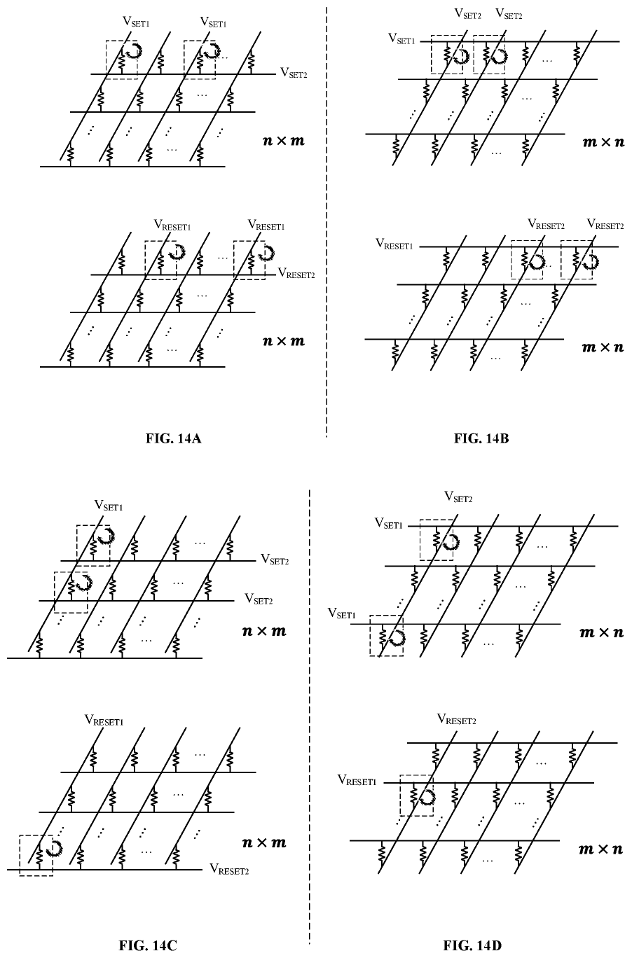

FIGS. 14A˜14D are schematic diagrams of example manners of an update operation provided by at least one embodiment of the present disclosure. FIG. 14A illustrates an example manner of performing an update operation row by row, in this example, assuming that the equivalent conductance weight parameter matrix of the memristor array is a nx m matrix, the weight parameter matrix n×m is updated row by row, in the case of updating a certain row of the weight parameter matrix n×m, for example, in the case of updating the conductance values of any two memristors that are not continuous on a certain row, for a memristor, the conductance value of which needs to be increased, in the certain row, V_{SET1} and V_{SET2} (for example, V_{SET1} and V_{SET2} are forward voltages) are applied to an upper electrode and a lower electrode of the memristor, for a memristor, the conductance value of which needs to be reduced, in the certain row, V_{RESET1} and V_{RESET2} (for example, V_{RESET1} and V_{RESET2} are reverse voltages) are applied to an upper electrode and a lower electrode of the memristor. FIG. 14B illustrates an example manner of performing an update operation row by row, in this example, assuming that the equivalent conductance weight parameter matrix of the memristor array is a n×m matrix, the weight parameter matrix n×m is updated row by row, in the case of updating a certain row of the weight parameter matrix n×m, for example, in the case of updating the conductance values of any two memristors that are continuous on a certain row, for a memristor, the conductance value of which needs to be increased, in the certain row, V_{SET1} and V_{SET2} (for example, V_{SET1} and V_{SET2} are forward voltages) are applied to an upper electrode and a lower electrode of the memristor, for a memristor, the conductance value of which needs to be reduced, in the certain row, V_{RESET1} and V_{RESET2} (for example, V_{RESET1} and V_{RESET2} are reverse voltages) are applied to an upper electrode and a lower electrode of the memristor. FIG. 14C illustrates an example manner of performing an update operation column by column, in this example, assuming that the equivalent conductance weight parameter matrix of the memristor array is a n×m matrix, the weight parameter matrix n×m is updated column by column, in the case of updating a certain column of the weight parameter matrix n×m, for example, in the case of updating the conductance values of any two memristors that are continuous on a certain column or updating the conductance value of a memristor located at an end of the certain column, for a memristor, the conductance value of which needs to be increased, in the certain column, V_{SET1} and V_{SET2} (for example, V_{SET1} and V_{SET2} are forward voltages) are applied to an upper electrode and a lower electrode of the memristor, for a memristor, the conductance value of which needs to be reduced, in the certain column, VRESET1 and V_{RESET2} (for example, V_{RESET1} and V_{RESET2} are reverse voltages) are applied to an upper electrode and a lower electrode of the memristor. FIG. 14D illustrates an example manner of performing an update operation column by column, in this example, assuming that the equivalent conductance weight parameter matrix of the memristor array is a n×m matrix, the weight parameter matrix n×m is updated column by column, in the case of updating a certain column of the weight parameter matrix n×m, for example, in the case of updating the conductance values of any two memristors that are not continuous on a certain column or updating the conductance value of a memristor located at the middle of the certain column, for a memristor, the conductance value of which needs to be increased, in the certain column, V_{SET1} and V_{SET2} (for example, V_{SET1} and V_{SET2} are forward voltages) are applied to an upper electrode and a lower electrode of the memristor, for a memristor, the conductance value of which needs to be reduced, in the certain column, V_{RESET1} and V_{RESET2} (for example, V_{RESET1} and V_{RESET2} are reverse voltages) are applied to an upper electrode and a lower electrode of the memristor

For example, in the training method provided in at least one embodiment of the present disclosure, only part of the training set data is used for the on-chip training process. For example, the data set A is used in the case of performing the off-chip training and the data B is used in the case of performing the on-chip training, where B is a subset of A.

For example, when training the memristor array through the forward calculation operation and the reverse calculation operation, only part of the training set data is used. For example, the data set A is used in the case of performing off-chip training, and the data B is used in the case of performing the forward calculation operation and the reverse calculation operation, where B is a subset of A.

The on-chip training process (for example, the forward calculation operation and the reverse calculation operation) using only part of the training set can reduce the amount of computation in the on-chip training process (for example, the forward calculation operation and the reverse calculation operation), simplify the system complexity, and reduce the system overhead.

For example, in the training method provided in at least one embodiment of the present disclosure, a last layer or last several layers of weight parameters of in the neural network are updated. For example, in step S120, the last layer or the last several layers of weight parameters in the neural network can be updated by adjusting at least part of the conductance values of the memristor array. For example, in step S122, a forward voltage or a reverse voltage is applied to the at least part of the memristors of the memristor arrays in the last layer or the last several layers of the neural network based on the result of the forward calculation operation and the result of the reverse calculation operation, so as to update the weight parameters corresponding to the at least part of the memristors of the memristor arrays in the last layer or the last several layers of the neural network.

For example, the training method provided by at least one embodiment of the present disclosure further includes: the memristor array calculating and outputting the output result of the neural network based on the updated weight parameters. For example, the input layer of the neural network after being hybrid-trained inputs the data, and the output result of the neural network are output at the output layer of the neural network after being hybrid-trained. For example, in the process of outputting the data, the output data of the neural network after being hybrid-trained is discretized, that is, is converted into a digital signal.

For example, an on-chip training unit may be provided, and at least part of the conductance values of the memristor array may be adjusted by the on-chip training unit to update the at least one layer of weight parameters of the neural network; for example, the on-chip training unit may be implemented as a memristor array.

It should be noted that, in the embodiments of the present disclosure, the flow of the training method may include more or fewer operations, and these operations may be performed sequentially or in parallel. Although the flow of the training method described above includes a plurality of operations occurring in a specific order, it should be clearly understood that the order of the plurality of operations is not limited. The training method described above can be performed once, or can be performed several times according to predetermined conditions.

The training method provided by the embodiments of the present disclosure makes up for the shortcomings of the on-chip training method and the off-chip training method used in the case where the neural network system is deployed in the hardware system based on the memristor array, and from the perspective of the neural network system, the training method solves the problems, such as the performance degradation of the neural network system caused by non-ideal characteristics such as device fluctuations, and efficiently and cost-effectively deploys various neural networks in the hardware system based on the memristor array.

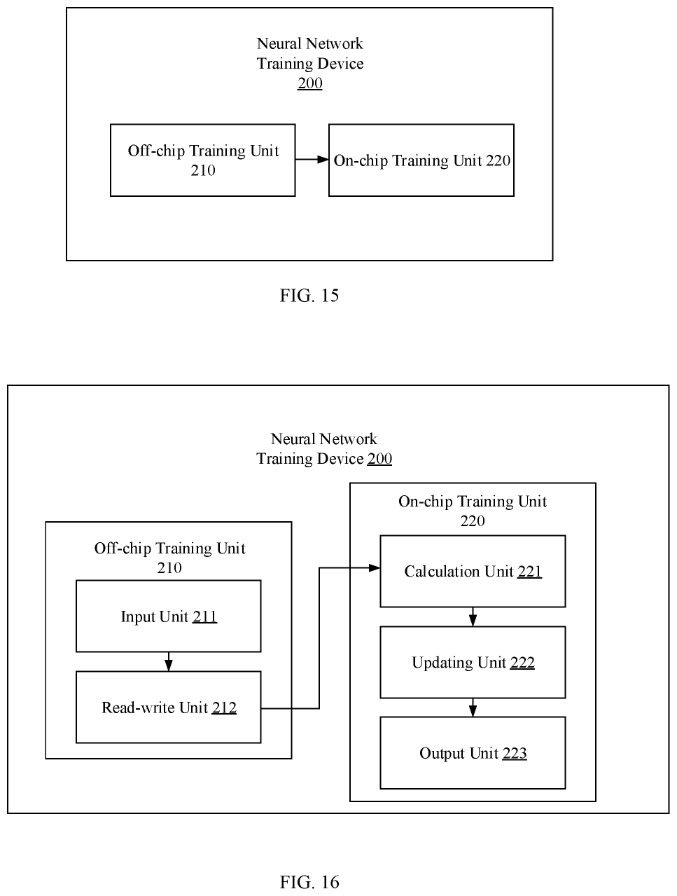

FIG. 15 is a schematic block diagram of a training device for a neural network provided in at least one embodiment of the present disclosure. For example, as shown in FIG. 15, the training device 200 includes an off-chip training unit 210 and an on-chip training unit 220. For example, these units may be implemented in the form of hardware (e.g., circuits), software, or firmware, and any combination thereof.

The off-chip training unit 210 is configured to train weight parameters of the neural network, and program a memristor array based on the weight parameters after being trained to write the weight parameters after being trained into the memristor array. For example, the off-chip training unit may implement step S110, and for a specific implementation method of the off-chip training unit, reference may be made to the relevant description of step S110, and details are not described herein again.

The on-chip training unit 220 is configured to update at least one layer of the weight parameters of the neural network by adjusting conductance values of at least part of memristors of the memristor array. For example, the on-chip training unit may implement step S120, and for a specific implementation method of the on-chip training unit, reference may be made to the relevant description of step S120, and details are not described herein again.

FIG. 16 is a schematic block diagram of an example of the training device for the neural network shown in FIG. 15. For example, as shown in FIG. 16, the off-chip training unit 210 includes an input unit 211 and a read-write unit 212, and the on-chip training unit 220 includes a calculation unit 221, an update unit 222, and an output unit 223. For example, these units may be implemented in the form of hardware (e.g., circuits), software, or firmware, and any combination thereof.

The input unit 211 is configured to input weight parameters after being trained. For example, the input unit 211 is connected to the input layer 11 of the neural network 10, and processes the data signal into the input data required by the neural network 10. For example, the input unit 211 can be implemented by, for example, hardware, software, firmware, or any combination thereof.

The read-write unit 212 is configured to write the weight parameters after being trained into the memristor array. For example, the read-write unit writes the weight parameters into the memristor array by applying a voltage (e.g., forward voltage or reverse voltage) to the memristor array. For example, the read-write unit can implement bidirectional write verification as shown in FIG. 9. For a specific implementation method, reference may be made to the related description of bidirectional write verification as shown in FIG. 9, and details are not described herein again.

The calculation unit 221 is configured to train the memristor array through a forward calculation operation and a reverse calculation operation. For example, the calculation unit may implement step S121, and for the specific implementation method, reference may be made to the relevant description of step S121, and details are not described herein again.

The updating unit 222 is configured to apply a forward voltage or a reverse voltage to at least part of memristors of the memristor array based on a result of the forward calculation operation and a result of the reverse calculation operation to update weight parameters corresponding to the at least part of the memristor array. For example, the calculation unit may implement step S122, and for a specific implementation method, reference may be made to the relevant description of step S122, and details are not described herein again.

The output unit 223 is configured to calculate an output result of the neural network based on the updated weight parameters. For example, the output unit 223 is connected to the output layer 13 of the neural network 10 and outputs the output data of the neural network 10 after being hybrid-trained. For example, the output unit 223 can be implemented by, for example, hardware, software, firmware, or any combination thereof. For example, the output unit 223 may perform discrete processing operation on the output data of the neural network 10 after being hybrid-trained through an ADC (Analog-to-Digital Converter), that is, converting the output data into a digital signal.

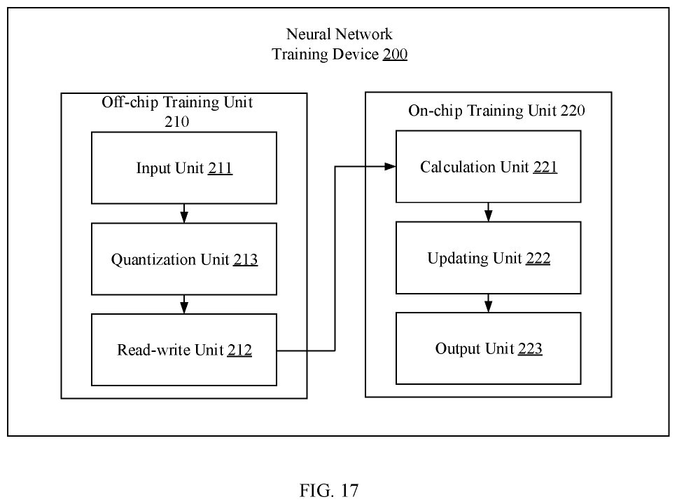

FIG. 17 is a schematic block diagram of an example of the training device for the neural network shown in FIG. 16. For example, as shown in FIG. 17, the off-chip training unit 210 further includes a quantization unit 213.

The quantization unit 213 is configured to, in a process of training the weight parameters of the neural network, according to a constraint of a conductance state of the memristor array, directly obtain quantized weight parameters of the neural network, and write the quantized weight parameters into the memristor array; or configured to perform a quantization operation on the weight parameters after being trained based on a constraint of a conductance state of the memristor array to obtain quantized weight parameters. For example, the quantization unit may implement step S111, and for a specific implementation method, reference may be made to the relevant description of step S111, and details are not described herein again; or, the quantization unit may also implement step S112, and for a specific implementation method, reference may be made to the relevant description of step S112, and details are not described herein again.

For example, in the training device provided in at least one embodiment of the present disclosure, the calculation unit 221 only performs the reverse calculation operation on at least part of the memristors of the memristor array. The specific implementation method is as described above, and details are not described herein.

For example, in the training device provided in at least one embodiment of the present disclosure, the calculation unit 221 performs the forward calculation operation and the reverse calculation operation row by row or column by row or in parallel as a whole, and for a specific implementation method, reference may be made to related descriptions about FIGS. 12A˜12D and FIGS. 13A˜13D, and details are not described herein again.

For example, in the training device provided in at least one embodiment of the present disclosure, the update unit performs the update operation row by row or column by column, and for a specific implementation method, reference may be made to the related description about FIGS. 14A˜14D, and details are not described herein again.

For example, in the training device provided in at least one embodiment of the present disclosure, the on-chip training unit is further configured to update the weight parameters of the last layer or the last several layers in the neural network, the specific implementation method is as described above, and details are not described herein again.

It should be noted that, for the sake of clarity and conciseness, the embodiments of the present disclosure do not provide all the constituent units of the training device 200 for the neural network. In order to achieve the necessary functions of the training device 200, those skilled in the art may provide and set other constituent units not shown according to specific needs, and the embodiments of the present disclosure are not limited thereto.

For the technical effects of the training device 200 in different embodiments, reference may be made to the technical effects of the training method for the neural network provided in the embodiments of the present disclosure, and details are not described here.

The following statements should be noted:

(1) The accompanying drawings involve only the structure(s) in connection with the embodiment(s) of the present disclosure, and other structure(s) can refer to common design(s).

(2) In case of no conflict, the embodiments of the present disclosure and the features in the embodiments can be combined with each other to obtain new embodiments.

What have been described above are only exemplary implementations of the present disclosure, and are not intended to limit the protection scope of the present disclosure, and the protection scope of the present disclosure should be determined by the appended claims.

1. A training method for a neural network based on memristors, wherein the neural network comprises a plurality of neuron layers connected one by one and weight parameters between the plurality of neuron layers, and the training method comprises:
training the weight parameters of the neural network, and programming a memristor array based on the weight parameters after being trained to write the weight parameters after being trained into the memristor array; and
updating a critical layer or several critical layers of the weight parameters of the neural network by adjusting conductance values of at least part of memristors of the memristor array.

2. The training method according to claim 1, wherein training the weight parameters of the neural network, and programming the memristor array based on the weight parameters after being trained to write the weight parameters after being trained into the memristor array, comprises:
in a process of training the weight parameters of the neural network, according to a constraint of a conductance state of the memristor array, directly obtaining quantized weight parameters of the neural network, and writing the quantized weight parameters into the memristor array.

3. The training method according to claim 1, wherein training the weight parameters of the neural network, and programming the memristor array based on the weight parameters after being trained to write the weight parameters after being trained into the memristor array, comprises:
performing a quantization operation on the weight parameters after being trained based on a constraint of a conductance state of the memristor array to obtain quantized weight parameters; and
writing the quantized weight parameters into the memristor array.

4. The training method according to claim 3, wherein the quantization operation comprises uniform quantization and non-uniform quantization.

5. The training method according to claim 2, wherein writing the quantized weight parameters into the memristor array, comprises:
acquiring a target interval of the conductance state of the memristor array based on the quantized weight parameters;
judging whether conductance states of respective memristors of the memristor array are within the target interval or not;
if not, judging whether the conductance states of the respective memristors of the memristor array exceeds the target interval,
if yes, applying a reverse pulse; and
if not, applying a forward pulse; and
if yes, writing the quantized weight parameters into the memristor array.

6. The training method according to claim 1, wherein updating the at least one layer of the weight parameters of the neural network by adjusting the conductance values of the at least part of memristors of the memristor array, comprises:
training the memristor array through a forward calculation operation and a reverse calculation operation; and
applying a forward voltage or a reverse voltage to the at least part of memristors of the memristor array based on a result of the forward calculation operation and a result of the reverse calculation operation to update the conductance values of the at least part of memristors of the memristor array.

7. The training method according to claim 6, wherein the reverse calculation operation is performed only on the at least part of memristors of the memristor array.

8. The training method according to claim 6, wherein the memristor array comprises memristors arranged in an array with a plurality of rows and a plurality of columns, and training the memristor array through the forward calculation operation and the reverse calculation operation comprises:
performing the forward calculation operation and the reverse calculation operation on the memristors, which are arranged in the plurality of rows and the plurality of columns, of the memristor array row by row or column by column or in parallel as a whole.

9. The training method according to claim 6, wherein weight parameters corresponding to the at least part of memristors of the memristor array are updated row by row or column by column.

10. The training method according to claim 6, wherein the forward calculation operation and the reverse calculation operation use only part of training set data to train the memristor array.

11. The training method according to claim 1, wherein updating the critical layer or several critical layers of the weight parameters of the neural network by adjusting the conductance values of the at least part of memristors of the memristor array, comprises:
updating a last layer or last several layers of weight parameters in the neural network.

12. The training method according to claim 1, further comprising: by the memristor array, outputting an output result of the neural network based on the weight parameters that are updated.

13. A training device for a neural network based on memristors, comprising:
an off-chip training unit, configured to train weight parameters of the neural network, and program a memristor array based on the weight parameters after being trained to write the weight parameters after being trained into the memristor array; and an on-chip training unit, configured to update a critical layer or several critical layers of the weight parameters of the neural network by adjusting conductance values of at least part of memristors of the memristor array.

14. The training device according to claim 13, wherein the off-chip training unit comprises an input unit and a read-write unit, and the on-chip training unit comprises a calculation unit, an update unit, and an output unit;
the input unit is configured to input the weight parameters after being trained;
the read-write unit is configured to write the weight parameters after being trained into the memristor array;
the calculation unit is configured to train the memristor array through a forward calculation operation and a reverse calculation operation;
the update unit is configured to apply a forward voltage or a reverse voltage to the at least part of memristors of the memristor array based on a result of the forward calculation operation and a result of the reverse calculation operation to update weight parameters corresponding to the at least part of memristors of the memristor array; and
the output unit is configured to calculate an output result of the neural network based on the weight parameters that are updated.

15. The training device according to claim 14, wherein the off-chip training unit further comprises a quantization unit, the quantization unit is configured to, in a process of training the weight parameters of the neural network, according to a constraint of a conductance state of the memristor array, directly obtain quantized weight parameters of the neural network, and write the quantized weight parameters into the memristor array;
or configured to perform a quantization operation on the weight parameters after being trained based on the constraint of the conductance state of the memristor array to obtain the quantized weight parameters.

16. The training device according to claim 14, wherein the calculation unit is configured to perform the reverse calculation operation only on at least part of memristors of the memristor array.

17. The training device according to claim 14, wherein the memristor array comprises memristors arranged in an array with a plurality of rows and a plurality of columns, the calculation unit is configured to perform the forward calculation operation and the reverse calculation operation on the memristors, which are arranged in the plurality of rows and the plurality of columns, of the memristor array row by row or column by column or in parallel as a whole.

18. The training device according to claim 14, wherein the update unit is configured to update the weight parameters corresponding to the at least part of memristors of the memristor array row by row or column by column.

19. The training device according to claim 13, wherein the on-chip training unit is further configured to update a last layer or last several layers of weight parameters in the neural network.

20. The training method according to claim 4, wherein writing the quantized weight parameters into the memristor array, comprises:
acquiring a target interval of the conductance state of the memristor array based on the quantized weight parameters;
judging whether conductance states of respective memristors of the memristor array are within the target interval or not;
if not, judging whether the conductance states of the respective memristors of the memristor array exceeds the target interval,
if yes, applying a reverse pulse; and
if not, applying a forward pulse; and
if yes, writing the quantized weight parameters into the memristor array.
